(19) United States
(12) Patent Application Publication
(10) Pub. No.: US 2015/0069627 A1
(43) Pub. Date: Mar. 12, 2015

(54) INTERPOSER WAFER AND METHOD OF MANUFACTURING SAME

(71) Applicant: KABUSHIKI KAISHA TOSHIBA, Tokyo (JP)

(72) Inventor: Kenji KOJIMA, Kanagawa (JP)

(73) Assignee: KABUSHIKI KAISHA TOSHIBA, Tokyo (JP)

(21) Appl. No.: 14/213,573

(22) Filed: Mar. 14, 2014

Related U.S. Application Data
(60) Provisional application No. 61/874,551, filed on Sep. 6, 2013.

(51) Int. Cl. H01L 21/768; H01L 23/00; H01L 23/538

(52) U.S. Cl. CPC H01L 21/76813; H01L 23/5384; H01L 23/562
USPC 257/774; 438/620

(57) ABSTRACT

In one embodiment, a method of manufacturing an interposer wafer includes forming a first hole having a first depth on a first main surface of a semiconductor wafer. The method further includes forming a second hole having a second depth on the first main surface of the semiconductor wafer before forming the first hole or after forming the first hole, the second depth being shallower than the first depth. The method further includes forming an electrode in the first hole. The method further includes forming an alignment mark in the second hole.

### CROSS REFERENCE TO RELATED APPLICATION

This application is based upon and claims the benefit of priority from the prior U.S. Provisional Patent Application No. 61/874,551 filed on Sep. 6, 2013, the entire contents of which are incorporated herein by reference.

### FIELD

Embodiments described herein relate to an interposer wafer and a method of manufacturing the same.

### BACKGROUND

When a silicon interposer is manufactured, first holes for forming through electrodes called through silicon vias (TSVs) and second holes for forming alignment marks are simultaneously formed on a silicon wafer. Since the second holes are formed simultaneously with the first holes, the second holes have approximately the same or the half of the depth of the first holes. Even if the depth of the second holes is approximately the half of the depth of the first holes, the second holes are deep enough. Furthermore, an interval between the second holes is set significantly narrower than an interval between the first holes. Therefore, when the through electrodes and the alignment marks are expanded by a thermal process after the through electrodes and the alignment marks are formed, great stress is applied on the alignment marks that have been formed very densely and formed deeply enough. As a result, cracks may be generated, starting from the alignment marks.

### BRIEF DESCRIPTION OF THE DRAWINGS

FIGS. 1A and 1B are plan views illustrating a structure of an interposer wafer of a first embodiment;

FIGS. 2A and 2B are cross-sectional views illustrating the structure of the interposer wafer of the first embodiment;

FIGS. 3A to 10B are cross-sectional views illustrating a method of manufacturing the interposer wafer of the first embodiment;

FIGS. 11 and 12 are cross-sectional views illustrating a method of manufacturing an interposer of the first embodiment; and

FIG. 13 is a cross-sectional view illustrating a structure of a semiconductor device of the first embodiment.

### DETAILED DESCRIPTION

Embodiments will now be explained with reference to the accompanying drawings.

In one embodiment, a method of manufacturing an interposer wafer includes forming a first hole having a first depth on a first main surface of a semiconductor wafer. The method further includes forming a second hole having a second depth on the first main surface of the semiconductor wafer before forming the first hole or after forming the first hole, the second depth being shallower than the first depth. The method further includes forming an electrode in the first hole. The method further includes forming an alignment mark in the second hole.

### First Embodiment

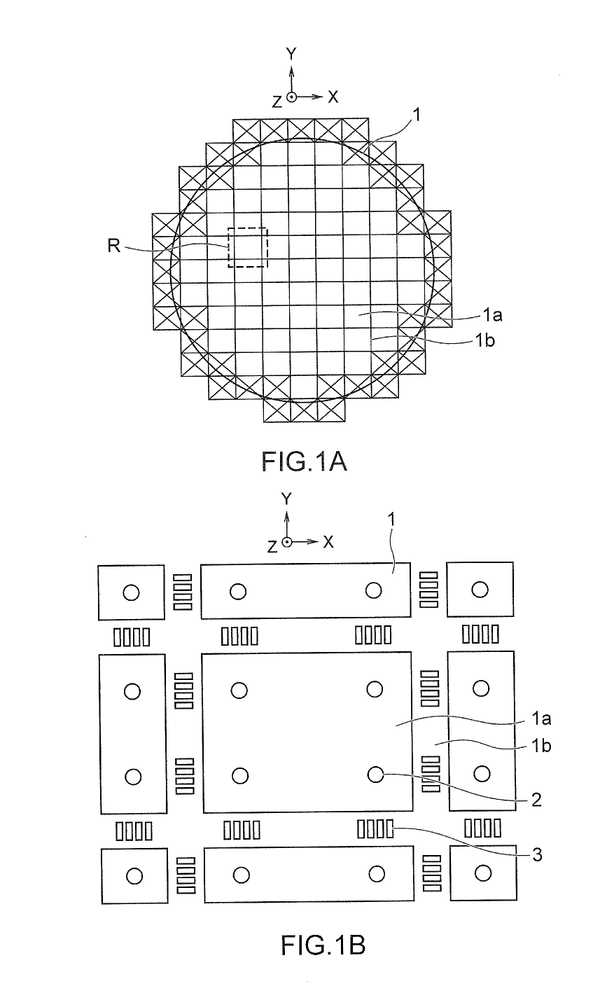

FIGS. 1A and 1B are plan views illustrating a structure of an interposer wafer of a first embodiment. FIG. 1B is an enlarged view of a region R illustrated in FIG. 1A.

The interposer wafer of the present embodiment includes a semiconductor wafer 1, a plurality of through electrodes (TSV) 2, and a plurality of alignment marks 3.

The semiconductor wafer 1 is, for example, a silicon wafer. FIGS. 1A and 1B illustrate X and Y directions which are parallel to a main surface of the semiconductor wafer 1 and perpendicular to each other, and a Z direction which is perpendicular to the main surface of the semiconductor wafer 1. The semiconductor wafer 1 includes chip regions 1a to be used as regions to form semiconductor chips, and scribe line regions 1b to be used as regions to form scribe lines.

The through electrodes 2 are formed in the chip regions 1a of the semiconductor wafer 1. The planar shape of each through electrode 2 is, for example, circular. The through electrodes 2 are an example of an electrode of the disclosure.

The alignment marks 3 are formed in the scribe line regions 1b of the semiconductor wafer 1. The planar shape of each alignment mark 3 is, for example, rectangular. When an interconnect layer or the like is formed on the semiconductor wafer 1, the alignment marks 3 are used as references for mask alignment.

It is noted that positions and numbers of the through electrodes 2 and the alignment marks 3 illustrated in FIG. 1B are schematic. The positions and the numbers of the through electrodes 2 and the alignment marks 3 are not limited to those illustrated in FIG. 1B.

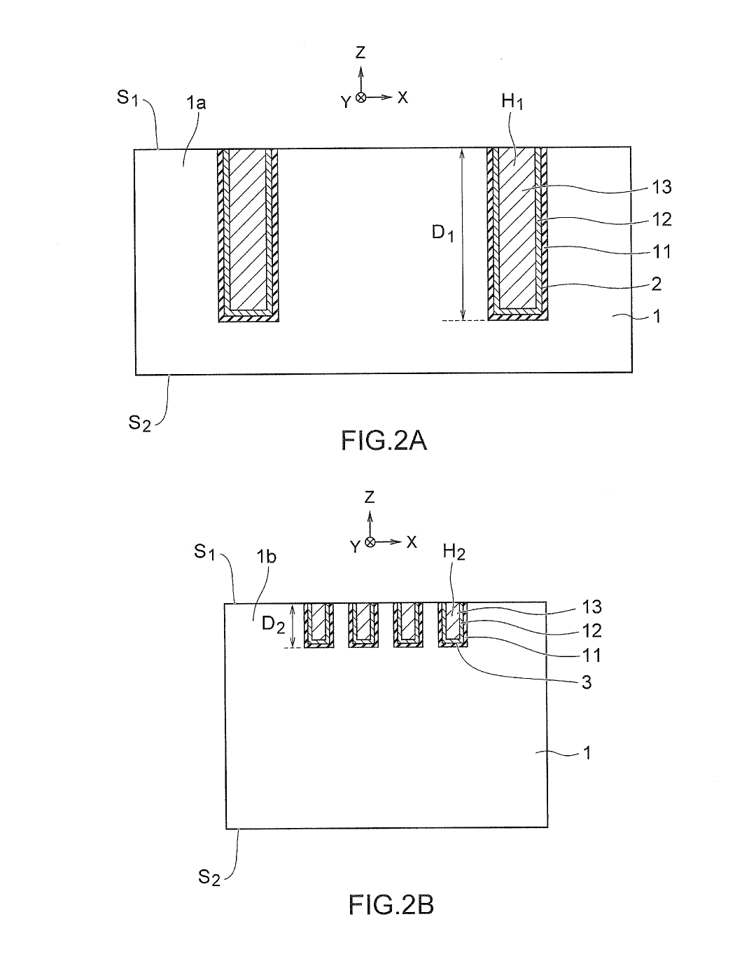

FIGS. 2A and 2B are cross-sectional views illustrating the structure of the interposer wafer of the first embodiment. FIGS. 2A and 2B illustrate cross sections of a chip region 1a and a scribe line region 1b, respectively.

The semiconductor wafer 1 includes first and second main surfaces S₁ and S₂. In addition, the semiconductor wafer 1 includes a plurality of first holes H₁ in the chip region 1a and a plurality of second holes H₂ in the scribe line region 1b.

In the present specification, a +Z direction is treated as an upward direction, and a −Z direction is treated as a downward direction. For example, a positional relationship between the first and second main surfaces S₁ and S₂ is represented that the first main surface S₁ is placed above the second main surface S₂.

The first holes H₁ are provided on the first main surface S₁ of the semiconductor wafer 1 and have a first depth D₁. The through electrodes 2 are formed in the first holes H₁.

The first depth D₁ is, for example, 50 to 100 μm. Also, a diameter of the first holes H₁ is, for example, 5 to 20 μm. In addition, an interval between the adjacent first holes H₁ is, for example, 40 to 100 μm.

The second holes H₂ are provided on the first main surface S₁ of the semiconductor wafer 1 and have a second depth D₂ which is shallower than the first depth D₁ (D₂<D₁). In the present embodiment, the second depth D₂ is set to 1/10 or less of the first depth D₁ (D₂≦D₁/10), from a perspective of preventing generation of cracks starting from the alignment marks 3. The alignment marks 3 are formed in the second holes H₂. Details about the prevention of the crack generation will be described below.

Similarly, from the perspective of preventing the crack generation, the second depth D₂ is desirably set to 10 μm or less, and more desirably to 2 μm or less. In the present embodiment, the second depth D₂ is set to, for example, 1 to 5 μm. Also, a width of the second holes H₂ in a short side direction is, for example, 0.5 to 1 μm. In addition, an interval between the adjacent second holes H₂ is, for example, 5 to 10 μm.

Each through electrode 2 includes a barrier metal layer 12 formed on side surfaces and a bottom surface of a first hole H₁ via an insulating layer 11, and a plug material layer 13 formed in the first hole H₁ via the insulating layer 11 and the barrier metal layer 12.

Similarly, each alignment mark 3 includes the barrier metal layer 12 formed on side surfaces and a bottom surface of a second hole H₂ via the insulating layer 11, and the plug material layer 13 formed in the second hole H₂ via the insulating layer 11 and the barrier metal layer 12.

The insulating layer 11 is, for example, a silicon oxide layer. The barrier metal layer 12 is, for example, a tantalum (Ta) layer or a tantalum nitride (TaN) layer. The plug material layer 13 is, for example, a copper (Cu) layer.

### (1) Effects of Interposer Wafer of First Embodiment

Continuously referring to FIGS. 2A and 2B, effects of the interposer wafer of the first embodiment will be described.

Conventionally, since the second holes H₂ for forming the alignment marks 3 are formed simultaneously with the first holes H₁ for forming the through electrodes 2, the second holes H₂ have approximately the same or the half of the depth of the first holes H₁. Even if the depth of the second holes H₂ is approximately the half of the depth of the first holes H₁, the second holes H₂ are deep enough. Furthermore, the interval between the second holes H₂ is normally set significantly narrower than the interval between the first holes H₁. Therefore, when the through electrodes 2 and the alignment marks 3 are expanded by a thermal process after the through electrodes 2 or the alignment marks 3 are formed, great stress is applied on the alignment marks 3 that have been formed very densely and formed deeply enough. As a result, cracks may be generated, starting from the alignment marks 3. The thermal process is, for example, performed in a process of forming an interconnect layer on the semiconductor wafer 1.

This is likely to become a problem in a case where a silicon wafer is used as the semiconductor wafer 1 and copper is used to form the through electrodes 2 and the alignment marks 3. The reason is that a difference in coefficients of thermal expansion between silicon and copper is large.

Accordingly, the second holes H₂ of the present embodiment are formed in a process different from a process of forming the first holes H₁. Consequently, according to the present embodiment, the second depth D₂ can be made sufficiently shallower than the first depth D₁. When the second depth D₂ is made shallow, the volume of the alignment marks 3 are decreased, and the volume difference between the volume before the thermal expansion of the alignment marks 3 and the volume after the thermal expansion of the alignment marks 3 becomes small. Therefore, according to the present embodiment, the stress applied on the alignment marks 3 can be reduced by making the second depth D₂ shallower than the first depth D₁, so that the generation of the cracks starting from the alignment marks 3 can be prevented.

An experiment on the thermal expansion of the alignment marks 3 was performed. In a case where the first depth D₁ was 100 μm and the second depth D₂ was tens of μm (i.e., a case where D₂ was tens of % of D₁) in the experiment, the cracks starting from the alignment marks 3 were generated. However, in a case where the second depth D₂ was a few μm (i.e., a case where D₂ was a few % of D₁) in the experiment, the cracks starting from the alignment marks 3 were not generated. Accordingly, it is assumed that, when the second depth D₂ is roughly 10% or less of the first depth D₁, the generation of the cracks can be prevented. Therefore, the second depth D₂ of the present embodiment is set to 1/10 or less of the first depth D₁. This means that in a case where the first depth D₁ is about 100 μm, the second depth D₂ is set to 10 μm or less.

When the first and second holes H₁ and H₂ are formed in different processes, the second holes H₂ may be formed before forming the first holes H₁, or may be formed after forming the first holes H₁.

Although the first and second holes H₁ and H₂ of the present embodiment are formed in different processes, the through electrodes 2 and the alignment marks 3 of the present embodiment may be formed simultaneously in the same process or may be formed in different processes.

FIGS. 2A and 2B illustrate an example of forming the through electrodes 2 and the alignment marks 3 in the same process. Accordingly, the through electrodes 2 and the alignment marks 3 in FIGS. 2A and 2B are formed of the same material which includes the barrier metal layer 12 and the plug material layer 13.

On the other hand, when the through electrodes 2 and the alignment marks 3 are formed in different processes, the through electrodes 2 and the alignment marks 3 may be formed of the same material or may be formed of different materials. For example, in a case where the through electrodes 2 are formed by using copper, the alignment marks 3 may be formed by using copper or may be formed by using aluminum or tungsten.

### (2) Method of Manufacturing Interposer Wafer of First Embodiment

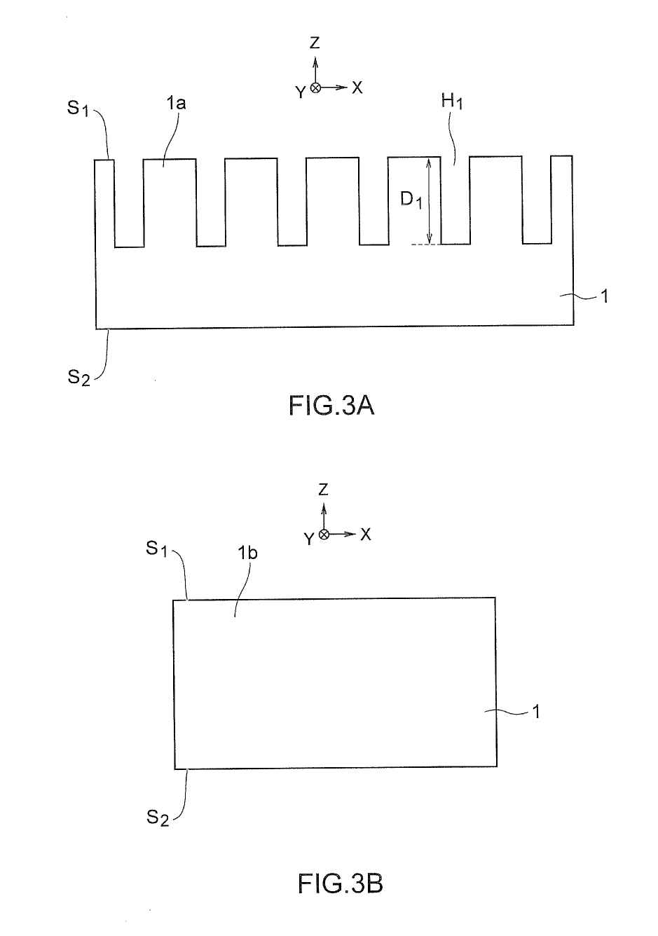

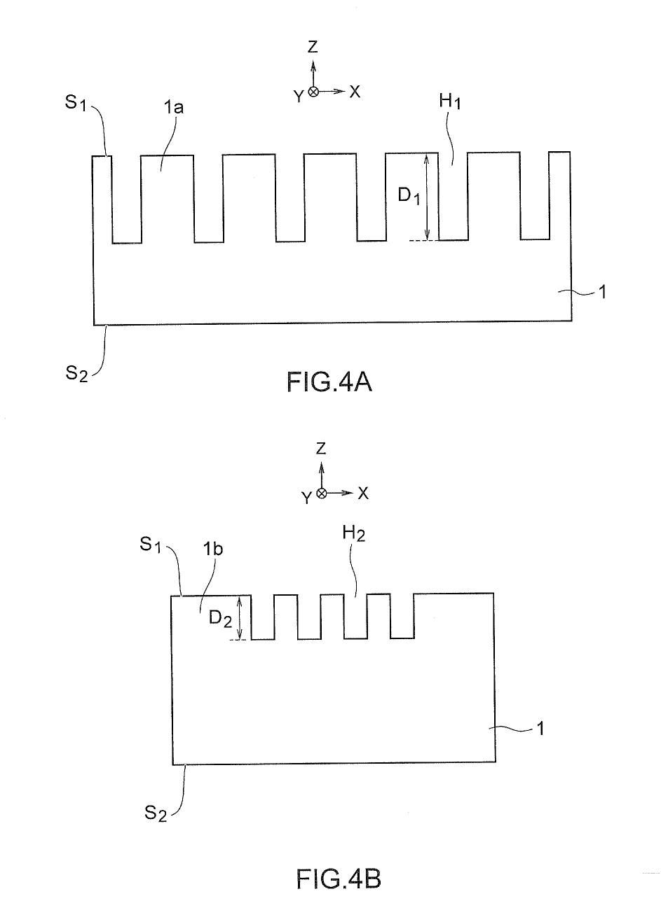

FIGS. 3A to 10B are cross-sectional views illustrating a method of manufacturing the interposer wafer of the first embodiment. FIGS. 3A and 3B illustrate cross sections of a chip region 1a and a scribe line region 1b of the semiconductor wafer 1, respectively. The same applies to FIGS. 4A to 10B.

First, as illustrated in FIGS. 3A and 3B, the first holes H₁ having the first depth D₁ are formed on the first main surface S₁ of the semiconductor wafer 1 by lithography and etching. The first holes H₁ are formed in the chip region 1a of the semiconductor wafer 1.

Next, as illustrated in FIGS. 4A and 4B, the second holes H₂ having the second depth D₂ shallower than the first depth D₁ are formed on the first main surface S₁ of the semiconductor wafer 1 by lithography and etching. The second holes H₂ are formed in the scribe line region 1b of the semiconductor wafer 1. In the present embodiment, the second depth D₂ is set to 1/10 or less of the first depth D₁.

The processes of FIGS. 4A and 4B may be performed before performing the processes of FIGS. 3A and 3B. In other words, the order of performing these processes may be changed.

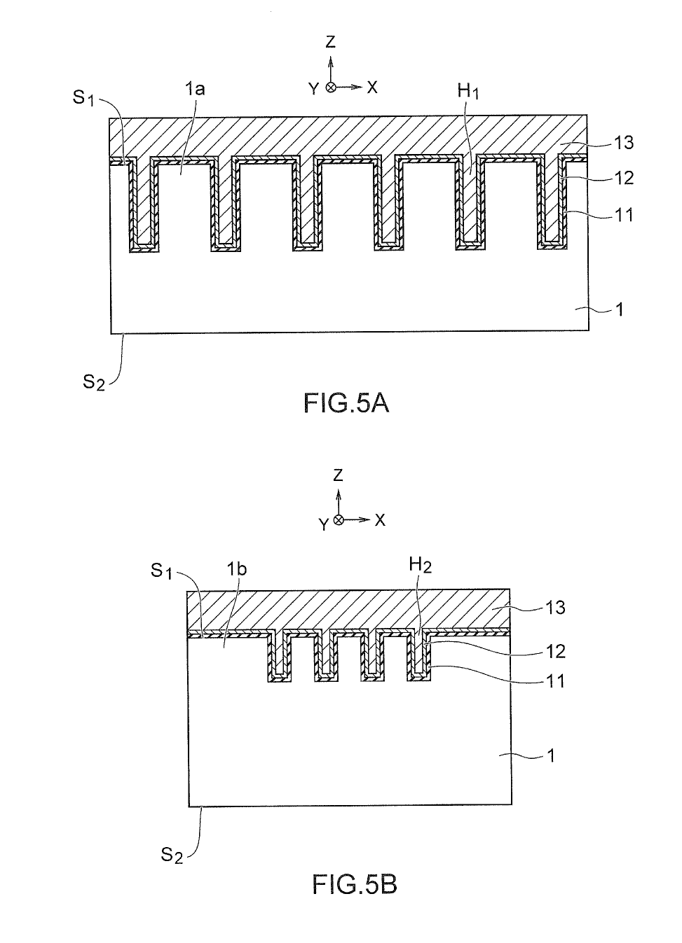

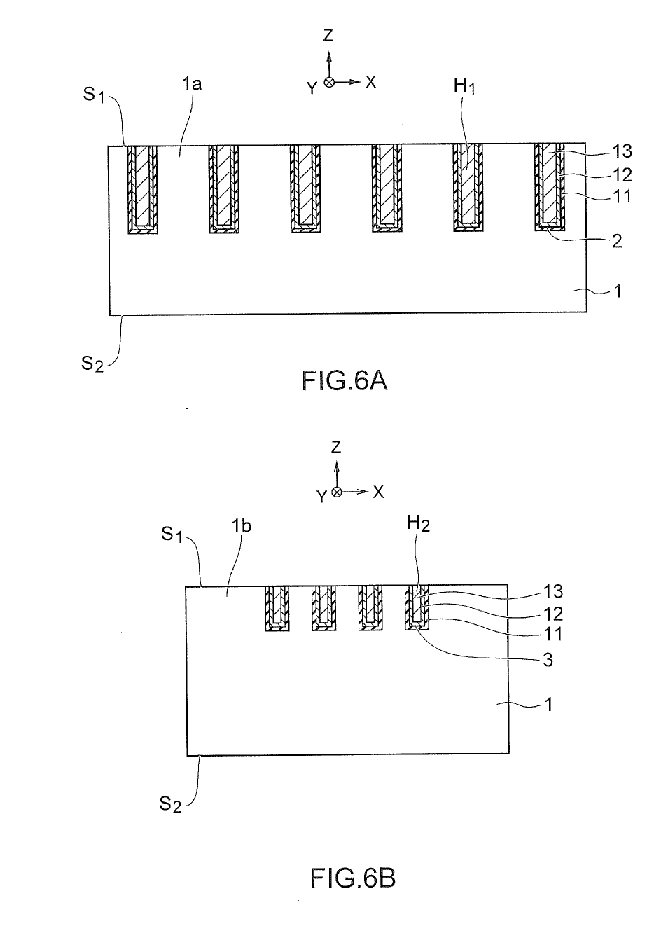

Next, as illustrated in FIGS. 5A and 5B, the insulating layer 11, the barrier metal layer 12 and the plug material layer 13 are sequentially formed on the entire surface of the semiconductor wafer 1. As illustrated in FIGS. 6A and 6B, the surface of the wafer is then polished by chemical mechanical polishing (CMP) until it reaches the first main surface S₁. As a result, the through electrodes 2 and the alignment marks 3 are formed in the first and second holes H₁ and H₂, respectively.

The through electrodes 2 and the alignment marks 3 of the present embodiment are formed by simultaneously embedding an embedding material (including the insulating layer 11, the barrier metal layer 12 and the plug material layer 13) in the first and second holes H₁ and H₂. In other words, the through electrodes 2 and the alignment marks 3 of the present embodiment are formed by the same embedding process.

However, the through electrodes 2 and the alignment marks 3 may be formed by respectively embedding first and second embedding materials in the first and second holes H₁ and H₂ in different processes. In this case, the embedding process of the second embedding material may be performed before the embedding process of the first embedding material, or may be performed after the embedding process of the first embedding material. In this case, the insulating layer 11, the barrier metal layer 12 and the plug material layer 13 may be used as the first embedding material, and a material which is same as or different from the first embedding material may be used as the second embedding material.

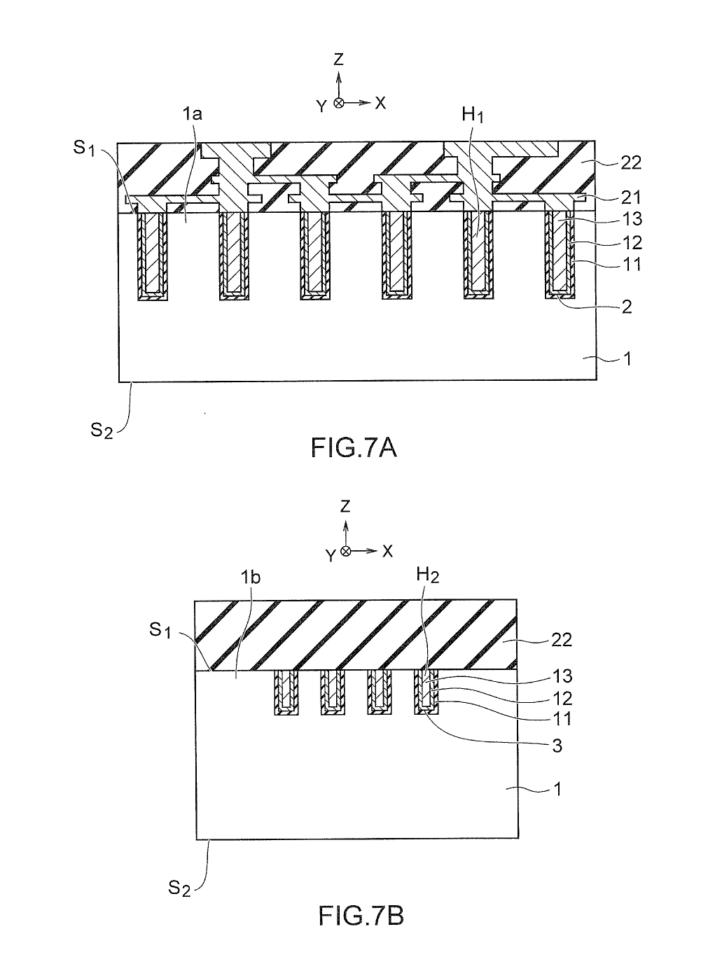

Next, as illustrated in FIGS. 7A and 7B, one or more interconnect layers 21 which are electrically connected to the through electrodes 2, and one or more inter layer dielectrics 22 are formed on the first main surface S₁ of the semiconductor wafer 1.

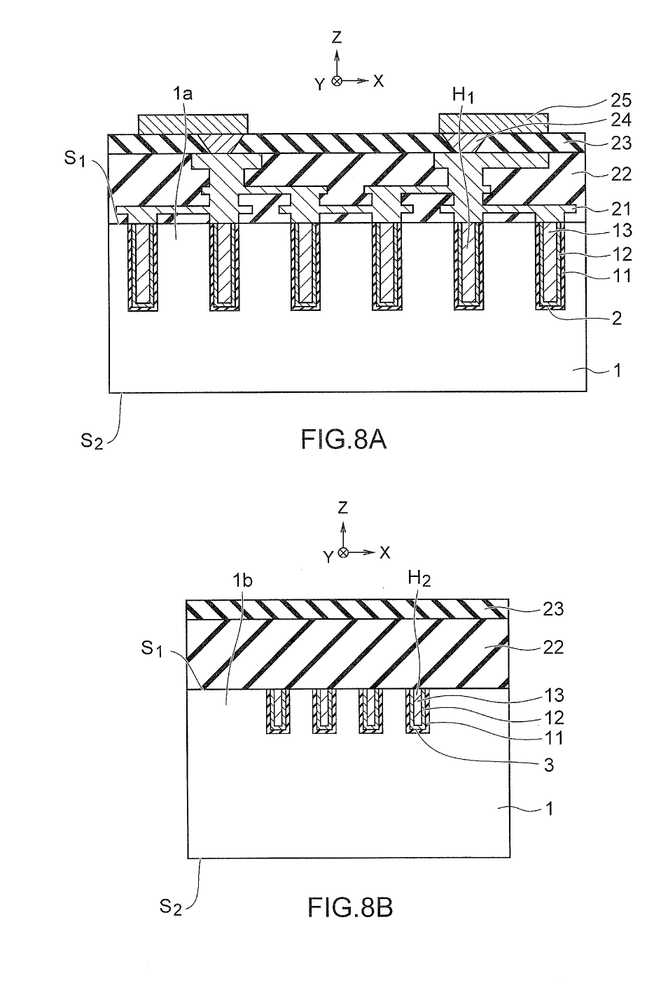

Next, as illustrated in FIGS. 8A and 8B, an inter layer dielectric 23, plugs 24 which are formed in the inter layer dielectric 23 and are electrically connected to the interconnect layers 21, and pads 25 which are electrically connected to the plugs 24, are formed on the inter layer dielectrics 22. The pads 25 are, for example, aluminum (Al) layers.

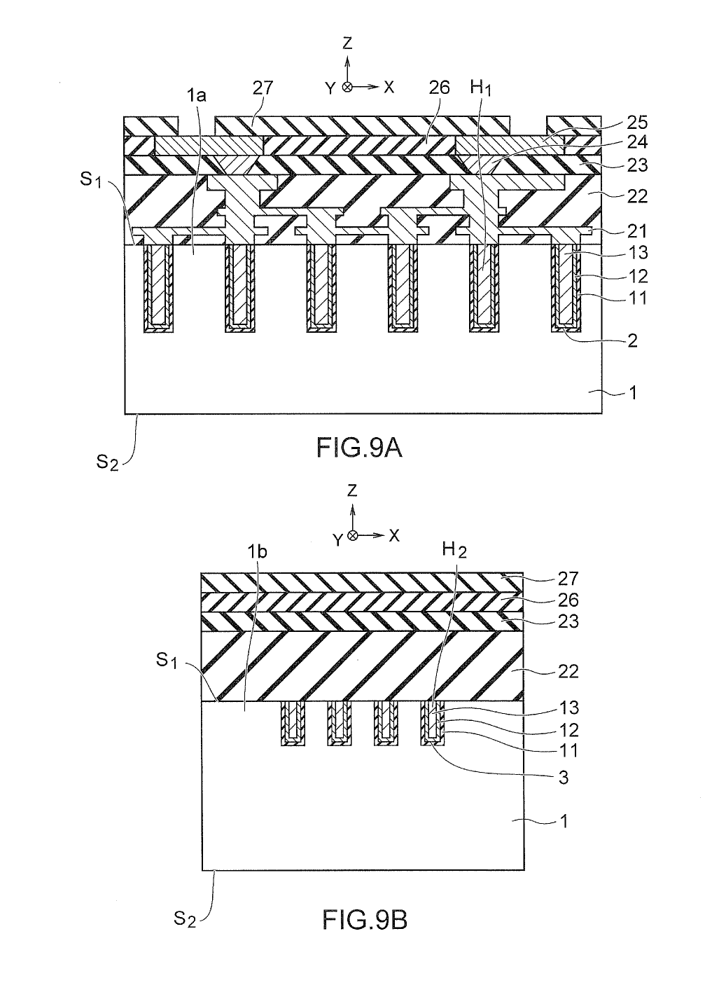

Next, as illustrated in FIGS. 9A and 9B, a passivation insulating layer 26 is formed on the inter layer dielectric 23, and openings are formed in the passivation insulating layer 26.

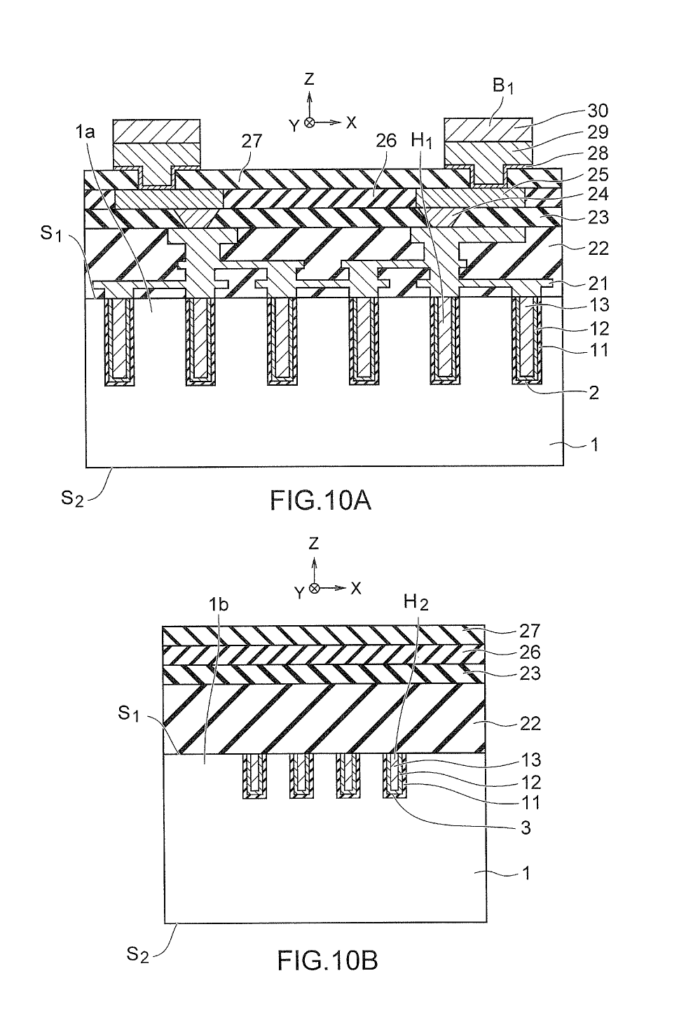

Next, as illustrated in FIGS. 10A and 10B, microbumps B₁ are formed on the pads 25 exposed in the openings of the passivation insulating layer 26. Each microbump B₁ is a stack layer including conductive layers 28, 29 and 30.

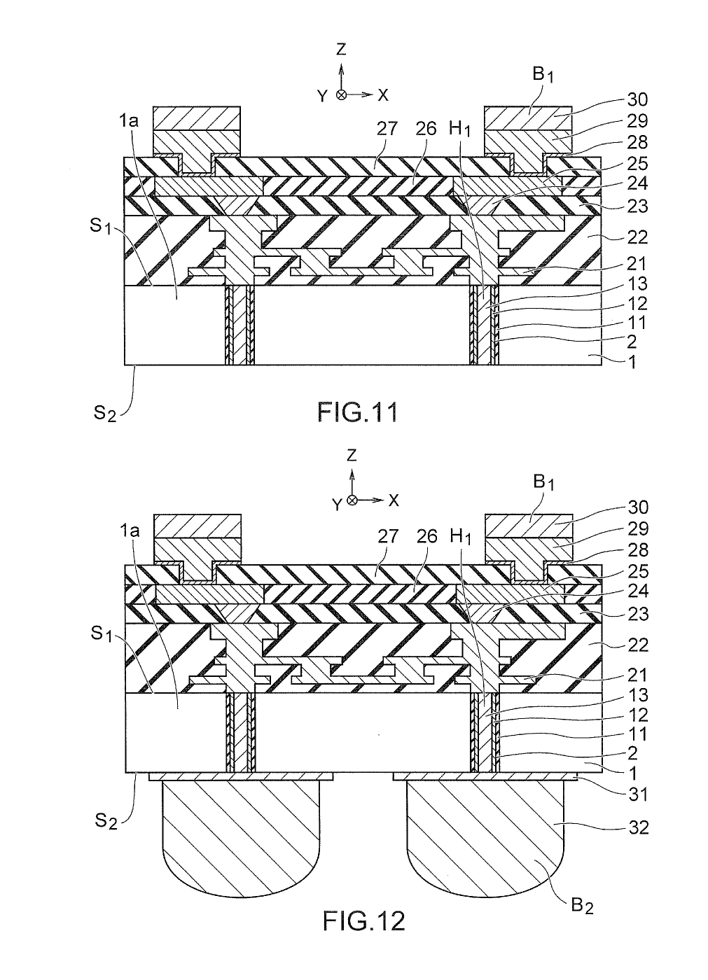

FIGS. 11 and 12 are cross-sectional views illustrating a method of manufacturing an interposer of the first embodiment. FIGS. 11 and 12 illustrate the cross section of the chip region 1a of the semiconductor wafer 1.

FIG. 11 illustrates a process following the process of FIG. 10. In the process of FIG. 11, the second main surface S₂ of the semiconductor wafer 1 is polished until the second main surface S₂ reaches the through electrodes 2. As a result, the through electrodes 2 are penetrated between the first main surface S₁ and the second main surface S₂ of the semiconductor wafer 1.

Next, as illustrated in FIG. 12, controlled collapse chip connection (C4) bumps B₂ are formed on the second surface S₂ of the semiconductor wafer 1. Each C4 bump B₂ is a stack layer including conductive layers 31 and 32. The C4 bumps B₂ are formed at positions where they are electrically connected to the through electrodes 2. The process of FIG. 12 is performed after dicing the semiconductor wafer 1 on the scribe lines.

In this way, a plurality of interposers are manufactured from one interposer wafer by the processes of FIGS. 3A to 12.

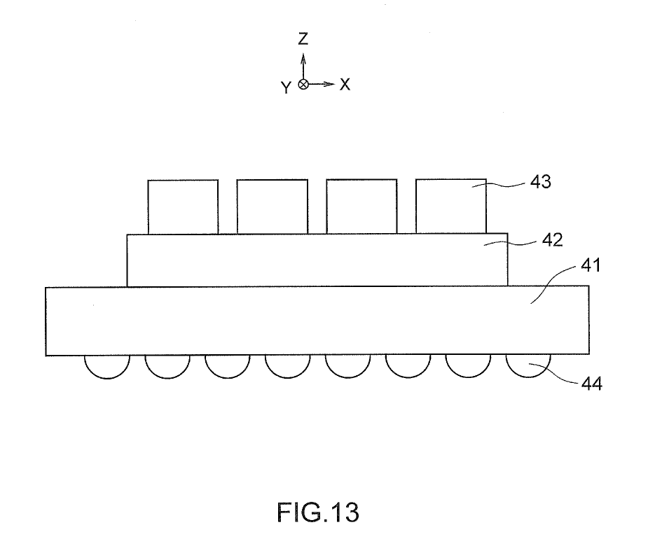

FIG. 13 is a cross-sectional view illustrating a structure of a semiconductor device of the first embodiment.

The semiconductor device of FIG. 13 includes a package substrate 41, an interposer 42 disposed on the package substrate 41, a plurality of LSI chips 43 disposed on the interposer 42, and a plurality of ball grid array (BGA) balls 44 provided on a back surface of the package substrate 41.

The LSI chips 43 are, for example, field-programmable gate array (FPGA) chips or memory chips. The interposer 42 is, for example, the silicon interposer manufactured by the processes of FIGS. 3A to 12.

The microbumps B₁ of the interposer 42 are electrically connected to the LSI chips 43. The C4 bumps B₂ of the interposer 42 are electrically connected to conductive layers provided on a front surface of the package substrate 41. As a result, the LSI chips 43 are electrically connected to each other via the interconnect layers 21 in the interposer 42 and conductive layers on the package substrate 41. The present embodiment makes it possible, by using the interposer 42, to realize a system in package (SiP) in which the LSI chips 43 are disposed on the package substrate 41 via the interposer 42.

The conductive layers provided on the front surface of the package substrate 41 are electrically connected to the conductive layers provided on the back surface of the package substrate 41 by, for example, through electrodes penetrating the package substrate 41. Furthermore, the package substrate 41 is disposed on a mother board via the BGA balls 44. The conductive layers provided on the back surface of the package substrate 41 are electrically connected to conductive layers provided on a surface of the mother board via the BGA balls 44.

As described above, the second holes H₂ for forming the alignment marks 3 of the present embodiment are formed in a process different from a process of the first holes H₁ for forming the through electrodes 2. Therefore, according to the present embodiment, the generation of the cracks starting from the alignment marks 3 can be prevented by making the second depth D₂ shallower than the first depth D₁ (for example, the second depth D₂ is set to 1/10 or less of the first depth D₁).

While certain embodiments have been described, these embodiments have been presented by way of example only, and are not intended to limit the scope of the inventions. Indeed, the novel wafers and methods described herein may be embodied in a variety of other forms; furthermore, various omissions, substitutions and changes in the form of the wafers and methods described herein may be made without departing from the spirit of the inventions. The accompanying claims and their equivalents are intended to cover such forms or modifications as would fall within the scope and spirit of the inventions.

1. A method of manufacturing an interposer wafer, comprising:
forming a first hole having a first depth on a first main surface of a semiconductor wafer;
forming a second hole having a second depth on the first main surface of the semiconductor wafer before forming the first hole or after forming the first hole, the second depth being shallower than the first depth;
forming an electrode in the first hole; and
forming an alignment mark in the second hole.

2. The method of claim 1, wherein the second depth is 1/10 or less of the first depth.

3. The method of claim 1, wherein the second depth is 10 μm or less.

4. The method of claim 1, wherein the electrode and the alignment mark are formed by simultaneously embedding an embedding material in the first and second holes.

5. The method of claim 4, wherein the embedding material comprises an insulating layer, a barrier metal layer formed on the insulating layer, and a plug material layer formed on the barrier metal layer.

6. The method of claim 1, wherein
the electrode is formed by embedding a first embedding material in the first hole, and
the alignment mark is formed by embedding a second embedding material in the second hole before embedding the first embedding material or after embedding the first embedding material.

7. The method of claim 6, wherein the first embedding material comprises an insulating layer, a barrier metal layer formed on the insulating layer, and a plug material layer formed on the barrier metal layer.

8. The method of claim 1, wherein the first hole is formed in a chip region of the semiconductor wafer.

9. The method of claim 1, wherein the second hole is formed in a scribe line region of the semiconductor wafer.

10. The method of claim 1, further comprising forming one or more interconnect layers which are electrically connected to the electrode, on the first main surface of the semiconductor wafer.

11. The method of claim 1, further comprising polishing a second main surface of the semiconductor wafer until the second main surface reaches the electrode, after forming the electrode and the alignment mark.

12. An interposer wafer comprising:
a semiconductor wafer having first and second main surfaces;
an electrode provided in a first hole which is provided on the first main surface of the semiconductor wafer and has a first depth; and
an alignment mark provided in a second hole which is provided on the first main surface of the semiconductor wafer and has a second depth which is 1/10 or less of the first depth.

13. The interposer wafer of claim 12, wherein the second depth is 10 μm or less.

14. The interposer wafer of claim 12, wherein the electrode and the alignment mark are formed of the same material.

15. The interposer wafer of claim 12, wherein the electrode and the alignment mark are formed of different materials.

16. The interposer wafer of claim 12, wherein the electrode comprises:
a barrier metal layer provided in the first hole; and
a plug material layer provided in the first hole via the barrier metal layer.

17. The interposer wafer of claim 16, wherein the barrier metal layer is provided in the first hole via an insulating layer.

18. The interposer wafer of claim 12, wherein the electrode is disposed in a chip region of the semiconductor wafer.

19. The interposer wafer of claim 12, wherein the alignment mark is disposed in a scribe line region of the semiconductor wafer.

20. The interposer wafer of claim 12, further comprising one or more interconnect layers disposed on the first main surface of the semiconductor wafer and electrically connected to the electrode.
